(19) United States
(12) Patent Application Publication
(10) Pub. No.: US 2006/0279209 A1
(43) Pub. Date: Dec. 14, 2006

(54) Self-emission panel, self-emission panel sealing member, and self-emission panel manufacturing method

(75) Inventors: Akihiko Yamaguchi, Yamagata (JP); Isamu Ohshita, Yamagata (JP)

Correspondence Address: ARENT FOX PLLC, 1050 CONNECTICUT AVENUE, N.W., SUITE 400, WASHINGTON, DC, 20036, US

(73) Assignee: TOHOKU PIONEER CORPORATION

(21) Appl. No.: 11/449,632

(22) Filed: Jun. 9, 2006

(30) Foreign Application Priority Data
Jun. 14, 2005 (JP) JP 2005-174320

(51) Int. Cl. H01J 1/62; H01J 63/04

(52) U.S. Cl. 313/512

(57) ABSTRACT

It is an object of the present invention to provide an improved display panel which is large in size and small in thickness without incurring any trouble, a self-emission panel sealing member, and a method of manufacturing the self-emission panel, by avoiding an undesired contact between a self-emission element section formed on a substrate (on one hand) and a sealing member or a desiccating member disposed within a sealing space (on the other), as well as by ensuring an adequate strength for the sealing member. A self-emission panel is fabricated by forming a self-emission element section on a substrate, followed by bonding together the substrate and a sealing member so as to form a sealing space, thereby allowing the self-emission element section to be disposed within the sealing space. In particular, the sealing member is adhesively supported on the substrate along an annular support portion arranged around the self-emission element section. Further, the sealing member has a concave portion formed on its inner surface facing the self-emission element section, its central area surrounded by the annular support portion being the deepest and the concave portion itself becoming shallow towards the support portion.

### BACKGROUND OF THE INVENTION

The present invention relates to a self-emission panel, a self-emission panel sealing member, and a self-emission panel manufacturing method.

The present application claims priority from Japanese Application No. 2005-174320, the disclosure of which is incorporated herein by reference.

Generally, an organic EL (Electroluminescence) panel includes a plurality of organic EL elements forming the basic structure thereof which is formed on a substrate. Each organic EL element includes a first electrode formed on the substrate, an organic layer formed on the first electrode and containing a luminescent layer consisting of an organic compound, and a second electrode formed on the organic layer. These organic EL elements are used as unit surface emission elements arranged on the substrate which is usually a flat member.

It has been known that the aforementioned organic EL panel will become deteriorated in its characteristic once the foregoing organic layer and electrodes are exposed to an outside air. This is because the moisture will infiltrate into interfaces between the organic layer and the electrodes and this can hamper the entering of electrons, causing dark spots which are non-luminescent areas and thus causing electrode corrosion. In order to improve the stability and durability of each organic EL element, it is indispensable to introduce an improved sealing technique capable of protecting the organic EL elements from the outside air. Generally, such sealing technique is realized by bonding, through an adhesive agent, a sealing member for covering electrodes and an organic layer on to a substrate on which the electrodes and the organic layer have already been formed.

FIGS. 1A and 1B show a prior art representing the above-mentioned organic EL panel (refer to Japanese Unexamined Patent Application Publication No. 2004-79467). As shown in FIG. 1A, an organic EL panel 1r comprises: i) asubstrate (glass substrate) 2; ii) an organic EL laminated body (self-emission element section) 3 consisting of an ITO (Indium Tin Oxide) electrode (first electrode), an organic luminescent material layer (organic layer), and a cathode (second electrode); iii) a sealing member (glass sealing member) 4; iv) a sealing material (adhesive agent) 5; and v) a desiccating member 6.

A self-emission panel such as an organic EL display panel is required to have a large display area and a small panel thickness so that it can provide an improved displaying performance and can be easily installed into an apparatus for mounting the display panel. On the other hand, if an organic EL display panel is simply increased in its size, an interval between the sealing member 4 and the substrate 2 will become large, resulting in a reduced pressing strength of the panel. Then, if an external force is applied to the panel through the substrate 2, the substrate 2 will become convex towards the sealing member 4 in a manner shown in FIG. 1B, causing a problem that the self-emission-element section 3 formed on the substrate 2 will probably get into contact with the desiccating member 6 and/or the inner surface of the sealing member 4. As a result, the self-emission element section 3 will probably be damaged, or a performance degradation factor will adhere to the front surface of the self-emission element section 3, causing the self-emission panel to have a deteriorated light emission performance and thus a shortened displaying life.

Moreover, in order to reduce the thickness of an organic EL display panel, if an effort has been made only to reduce an interval (clearance) between the self-emission element section 3 formed on the substrate 2 (on one hand) and the sealing member 4 or the desiccating member 6 (on the other), an external force applied on the substrate 2 will probably cause the above-mentioned undesired contact. If the foregoing clearance within the sealing space is to be ensured to some extent while the panel itself is still made to have a small thickness, an effort to simply reduce the thickness of the sealing member 4 will reduce the strength of the sealing member 4.

### SUMMARY OF THE INVENTION

The present invention is to solve the afore-mentioned problem and makes this as one of tasks of the invention. Namely, it is an object of the present invention to provide an improved display panel which is large in size and small in thickness without incurring any trouble, by avoiding an undesired contact between a self-emission element section formed on a substrate (on one hand) and a sealing member or a desiccating member disposed with a sealing space (on the other), as well as by ensuring an adequate strength for the sealing member, even when the substrate is bent.

[Means for Solving the Problem]

In order to achieve the above object, the present invention is characterized by at least the following aspects.

According to one aspect of the present invention, there is provided a self-emission panel fabricated by forming a self-emission element section on a substrate, followed by bonding together the substrate and a sealing member so as to form a sealing space to dispose the self-emission element section within the sealing space. In particular, the sealing member is adhesively supported on the substrate through a support portion disposed around the self-emission element section. Further, the sealing member has a concave portion formed on one surface thereof facing the self-emission element section, the concave portion's central area surrounded by the support portion being the deepest and the concave portion's other areas becoming shallow towards the support portion.

According to another aspect of the present invention, there is provided a sealing member for use in a self-emission panel, wherein a substrate having formed thereon a self-emission element section and a sealing member are bonded together to form a sealing space, thereby allowing the self-emission element section to be disposed within the sealing space. The sealing member comprises: a support portion formed to surround the self-emission element section and to be adhesively supported on the substrate; and a concave portion formed on one surface of the sealing member facing the self-emission element section, the concave portion's central area surrounded by the support portion being the deepest and the concave portion's other areas becoming shallow towards the support portion.

According to further aspect of the present invention, there is provided a method of manufacturing a self-emission panel formed by bonding together i) a substrate having formed thereon a self-emission element section and ii) a sealing member so as to form a sealing space, thereby allowing the self-emission element section to be disposed within the sealing space. This method comprises: a first step for forming the sealing member having a support portion to surround the self-emission element section and to be adhesively supported on the substrate, also having a concave portion formed on one surface of the sealing member facing the self-emission element section, the concave portion's central area surrounded by the support portion being the deepest and the concave portion's other areas becoming shallow towards the support portion; and a second step for bonding together the substrate and the sealing member formed in the first step through the support portion, in a manner such that the self-emission element section formed on the substrate is surrounded and covered by the sealing member.

### BRIEF DESCRIPTION OF THE DRAWINGS

These and other objects and advantages of the present invention will become clear from the following description with reference to the accompanying drawings, wherein:

FIGS. 1A and 1B are sectional views showing an organic EL panel, with FIG. 1A showing such an EL panel and FIG. 1B showing a problem associated with the EL panel;

FIG. 2 is a sectional view showing a self-emission panel formed according to a first embodiment of the present invention;

FIG. 3 is a sectional view showing an operation of the self-emission panel of FIG. 2;

FIG. 4 is a sectional view showing a self-emission panel 1a formed according to a second embodiment of the present invention;

FIG. 5 is a sectional view showing an operation of the self-emission panel 1a of FIG. 4;

FIGS. 6A, 6B, and 6C are sectional views showing self-emission panels of different embodiments of the present invention, with FIG. 6A representing a third embodiment, FIG. 6B a fourth embodiment, and FIG. 6C a fifth embodiment;

FIG. 7 is a flowchart showing a method of manufacturing a self-emission panel according to one embodiment of the present invention;

FIGS. 8A to 8C are sectional views showing a method of manufacturing self-emission panels according to another embodiment of the present invention;

FIG. 9 is a sectional view showing a self-emission panel formed according to a further embodiment of the present invention;

FIG. 10 is a sectional view showing a self-emission panel 1g formed according to a further embodiment of the present invention;

FIGS. 11A and 11B are sectional views showing a method of manufacturing a sealing member illustrated in FIG. 10, with FIG. 11A showing a press molding operation and FIG. 11B showing a sealing member formed during the press molding operation;

FIG. 12 is a sectional view showing a self-emission panel 1h formed according to another embodiment of the present invention; and

FIG. 13 is an explanatory sectional view showing an example of a self-emission panel formed according to one embodiment of the present invention.

### DETAILED DESCRIPTION OF THE PREFERRED EMBODIMENTS

A self-emission panel according to one embodiment of the present invention is formed by at first forming a self-emission element section on a substrate, followed by bonding together the substrate and a sealing member so as to form a sealing space, thereby allowing the self-emission element section to be disposed within the sealing space. Here, the sealing member is adhesively supported on the substrate along its annular support portion arranged around the self-emission element section. Further, the sealing member has a concave portion formed on its inner surface facing the self-emission element section, with its central area being the deepest and its edge area the shallowest.

Since the self-emission panel having the above-described structure is so formed that its sealing member has the afore-mentioned concave portion, it is allowed to neglect a situation in which the substrate is bent due to an external force or a pressure difference between the interior and exterior of the sealing space. Namely, the concave portion is made deepest near the center (at which the substrate bending is the largest) of an area surrounded by the annular support portion, so that it is possible for the self-emission element section formed on the substrate to avoid an undesired contact with other essential elements such as the inner surface of the sealing member. On the other hand, since the concave portion is made gradually shallow from the vicinity of the center towards the vicinity of the annular support portion so as to ensure an adequate thickness of the sealing member, it is possible to ensure an adequate strength for the sealing member. In this way, using the sealing member having the above-described structure, it becomes possible to produce a self-emission panel which is large in size and small in thickness, without bringing about any problems possibly caused by the aforementioned contact or an insufficient strength of the sealing member.

In the following, an embodiment of the present invention will be described with reference to the accompanying drawings.

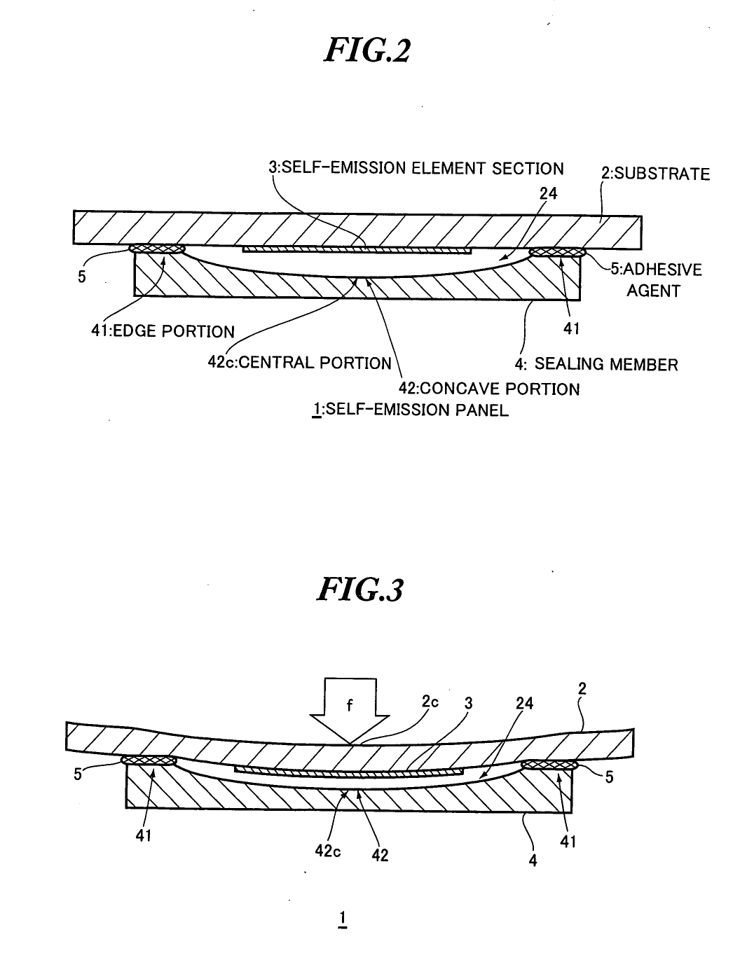

FIG. 2 is a sectional view showing a self-emission panel formed according to a first embodiment of the present invention. As shown in FIG. 2, the self-emission panel 1 of the present embodiment includes, as its essential elements, a substrate 2, a self-emission element section 3, a sealing member 4, and an adhesive agent 5. The self-emission element section 3 is formed on one surface of the substrate 2, while the sealing member 4 is formed to cover up the self-emission element section 3. In the present embodiment, the sealing member 4 and the substrate 2 are bonded together through the adhesive agent 5.

The self-emission element section 3 is composed of one or more self-emission elements each capable of emitting light by virtue of an electrical energy supplied from the outside. Such self-emission element section 3 in the present embodiment can be formed by at least one organic EL (Electro-luminescence) element. Such organic EL element includes a first electrode (ITO) serving as an anode which is formed on one surface of the substrate 2, an organic layer containing a luminescent layer consisting of an organic compound which is formed on the first electrode, and a second electrode serving as a cathode which is formed on the organic layer.

The sealing member 4 has a function of protecting the self-emission element section 3 from an outside air. In detail, the sealing member 4 is formed in a manner such that the self-emission element section 3 formed on the substrate 2 may be surrounded. Further, the sealing member 4 is bonded through the adhesive agent 5 on to the substrate 2 having formed thereon the self-emission element section 3, thereby covering the self-emission element section 3. Moreover, the sealing member 4 has an annular support portion 41 and a concave portion 42, as shown in FIG. 2.

As shown in FIG. 2, the annular support portion 41 is formed along the perimeter of the sealing member 4, surrounding the concave portion 42. When manufacturing the self-emission panel 1, the annular support portion 41 is bonded to the substrate 2 so as to surround the self-emission element section 3, thereby supporting the sealing member 4 on the substrate 2.

The concave portion 42 is formed on one surface of the sealing member 4 facing the self-emission element section 3. The central area 42c surrounded by the annular support portion 41 is the deepest and the depth of the concave portion 42 becomes gradually shallow towards the annular support portion 41. Preferably, the concave portion 42 is shaped so as to absorb a bending amount of the substrate 2 being bent into a sealing space 24 formed by bonding together the substrate 2 and the sealing member 4. On the other hand, it is also possible for the concave portion 42 to be shaped to absorb a predetermined bending amount or a substantially maximum bending amount of the substrate 2 being bent into the sealing space 24. In other words, the shape of the concave portion 42 is set in a manner such that the sealing member 4 will not get into contact with the substrate 2 or the self-emission element section 3 formed on the substrate 2, if the substrate 2 is bent in a predetermined bending amount or a substantially maximum bending amount.

Preferably, a maximum depth of the concave portion 42 is set to satisfy a maximum bending amount of the substrate 2 being bent into the sealing space 24 formed by bonding together the substrate 2 and the sealing member 4. More preferably, the maximum depth of the concave portion is set to be larger than the maximum bending amount of the substrate 2, thereby making it possible to exactly avoid an undesired contact between the substrate 2 and the inner surface of the sealing member 4. Further, it is also possible for a maximum depth of the concave portion 42 to be set to satisfy a predetermined bending amount of the substrate 2. In this way, if the substrate 2 is not at its maximum bending state, i.e., as long as a bending amount of the substrate 2 is within a predetermined amount, it is possible to exactly avoid the aforementioned undesired contact.

Moreover, as long as a shape of the concave portion 42 can prevent the aforementioned undesired contact, such a shape is allowed to be a curved surface or a stepped surface. Further, since the sealing member 4 of the present embodiment has the above-described concave portion 42, it is not necessary to reduce the thickness of the sealing member 4 except in the concave portion 42, thereby making it possible for the sealing member 4 to have a higher strength than a sealing member whose thickness has been uniformly reduced for reducing a total thickness of a display panel. In addition, it is preferable for the sealing member 4 to be formed in a manner such that a flat area of the concave portion 42 is narrower than an area occupied by the self-emission element section 3.

The adhesive agent 5 is used to bond together the substrate 2 and the sealing member 4. Such adhesive agent 5 may be a thermal-setting type, a chemical-setting type (two-liquid mixed), a light (ultraviolet light)-setting type or the like, using a material such as an acryl resin, an epoxy resin, a polyester, a polyolefin, or the like. In particular, it is preferable to use an ultraviolet light-setting epoxy resin. Practically, an adhesive agent is applied to either one or both of the substrate 2 and the sealing member 4 by virtue of application or printing, so as to form a pattern defining the sealing space 24. At this time, it is possible to add an appropriate amount (about 0.1 to 0.5 wt %) of spacers (preferably, glass or plastic spacers) having a size of 1 to 100 μm, thereby allowing the sealing space 24 to have a certain thickness depending on the size of the spacers.

FIG. 3 is an explanatory view showing an operation of the self-emission panel of FIG. 2. Therefore, the operation of the self-emission panel will be described below with reference to FIG. 3.

As shown, when there is a certain external force or a pressure difference between the interior and exterior of the sealing member 4, the substrate 2 will be bent in a manner shown in FIG. 3. At this time, since the sealing member 4 and the substrate 2 are adhesively combined with each other along the annular support portion 41 of the sealing member 4, a substantially central portion 2c of the substrate 2 will be bent towards the sealing member 4. At this moment, since the sealing member 4 has the concave portion 42 so shaped that it can absorb a bending of the substrate 2 when a bending amount is within a predetermined range or at its maximum value, the self-emission element section 3 formed on the substrate 2 will not get into contact with the inner surface of the sealing member 4.

As described above, in the self-emission panel 1 of the present embodiment, self-emission element section 3 is formed on the substrate 2 and disposed within the sealing space 24 formed by bonding together the substrate 2 and the sealing member 4. The sealing member 4 is supported on the substrate 2 through the annular support portion 41 surrounding the self-emission element section 3. The concave portion 42 is formed on the inner surface of the sealing member 4 facing the self-emission element section 3, in a manner such that it is the deepest in the central portion 42c surrounded by the annular support portion 41 and gradually becomes shallow towards the annular support portion 41. As a result, even when the substrate 2 is bent, it is still possible to prevent an undesired contact between the self-emission element section 3 formed on the substrate 2 (on one hand) and the inner surface of the sealing member 4 (on the other).

Moreover, even when the sealing space 24 surrounded by the annular support portion 41 has a relatively large width, the above-described concave portion 42 formed in the sealing member 4 makes it possible to produce an improved self-emission panel 1 which is large in size and small in thickness, without causing an undesired contact between the sealing member 4 and the self-emission element section 3 formed on the substrate 2.

Further, since the sealing member 4 has the above-described concave portion 42, as compared with a sealing member whose thickness has been uniformly reduced for reducing a total thickness of a display panel, it is possible to ensure a sufficient thickness in areas close to the annular support portion 41 except the concave portion 42, thereby ensuring a relatively high strength for the sealing member 4.

The concave portion 42 of the present embodiment may be made into a smoothly curved surface, or a specific configuration in which the concave inner surface presents straight lines in its side view, with its depth being the deepest in its center and becoming shallower towards the annular support portion 41. If the inner surface of the concave portion is formed into a curved surface, it is allowed to obtain a higher strength since it is easier to avoid a concentrated stress than a surface involving corner portions.

The maximum depth of the concave portion 42 of the sealing member 4 according to the present embodiment is set in response to the maximum bending amount of the substrate 2 being bent into the sealing space 24. Therefore, if the concave portion 42 is set to have a depth larger than the maximum bending amount of the substrate 2, it is possible to exactly prevent an undesired contact between the self-emission element section 3 and the sealing member 4 even if the substrate 2 is at its maximum bending state.

Further, if the configuration of the concave portion 42 of the sealing member 4 is set in response to a shape corresponding to a predetermined bending amount of the substrate 2, in more detail, if the depths of various areas of the concave portion 42 are set to be deeper than a predetermined bending amount of the substrate 2, it is possible to prevent an undesired contact between the self-emission element section 3 and the sealing member 4 when the substrate 2 is bent in a predetermined bending amount, thereby allowing the sealing member 4 to have an adequate thickness except in its concave portion.

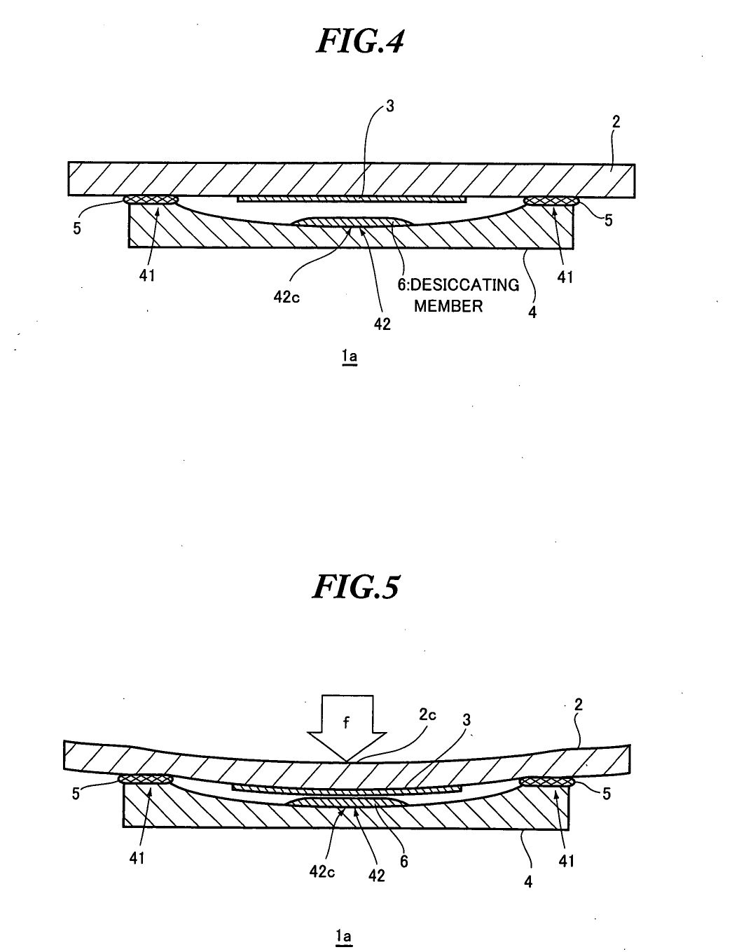

FIG. 4 is a sectional view showing another self-emission panel 1a formed according to a second embodiment of the present invention. As shown in FIG. 4, the self-emission panel 1a of the present embodiment contains a desiccating member 6 located within the sealing space 24. In detail, the desiccating member 6 is disposed on the inner surface of the sealing member 4 facing the substrate 2.

The desiccating member 6 is provided to absorb and thus remove an initial moisture existing from the beginning within the sealing space 24, an accumulated moisture generated gradually with the passing of time from the self-emission element section 3, or a moisture entering from the outside through the sealing member 4, all after the sealing member 4 and the substrate 2 have been bonded together. In particular, when an organic EL element is used as the self-emission element section 3, since an organic layer partially forming the organic EL element is weak with respect to a heat and thus it is impossible to remove a moisture by conducting a heating treatment before the above-mentioned bonding, the desiccating member 6 is disposed in the sealing space 24 so as to remove such a moisture. In practice, the desiccating member 6 can be formed by a compound capable of chemically absorbing a moisture and maintaining itself in a solid state even if it has absorbed a moisture.

Similar to the first embodiment, the sealing member 4 in the present embodiment has an annular support portion 41 and a concave portion 42. Here, the concave portion 42 is shaped by taking into account the desiccating member 6. Namely, the concave portion 42 is shaped to satisfy a bending amount of the substrate 2 being bent into the sealing space, as well as the shape, size, and thickness of the desiccating member 6. In more detail, the concave portion 42 is so shaped that it is possible to avoid an undesired contact between the self-emission element section 3 and the desiccating member 6 disposed on the inner surface of the concave portion 42, even if the substrate 2 is bent into the sealing space. For example, the concave portion 42 is so shaped that it has a depth which can prevent an undesired contact between the self-emission element section 3 and the desiccating member 6 disposed on the inner surface of the concave portion 42, even if the substrate 2 is bent into the sealing space in a predetermined bending amount or a maximum bending amount.

FIG. 5 is an explanatory view showing an operation of the self-emission panel 1a illustrated in FIG. 4. Although the self-emission panel 1a having the above-described structure is described with reference to FIG. 5, description of the elements and portions which are the same as those in the first embodiment will be partially omitted.

As shown in FIG. 5, when there is a certain external force or a pressure difference between the interior and the exterior of the sealing member 4, a substantially central portion 2c of the substrate 2 will be bent towards the sealing member 4. At this time, the sealing member 4 and the substrate 2 are supported on each other through the annular support portion 41. In this way, since the sealing member 4, in response to a situation in which the substrate 2 is bent into the sealing space in a predetermined bending amount or a maximum bending amount, has the concave portion 42 which is so deep that it can prevent an undesired contact between the sealing member 4 and the self-emission element section 3 formed on the substrate 2, it is possible to exactly avoid an undesired contact between the desiccating member 6 and the self-emission element section 3 formed on the substrate 2.

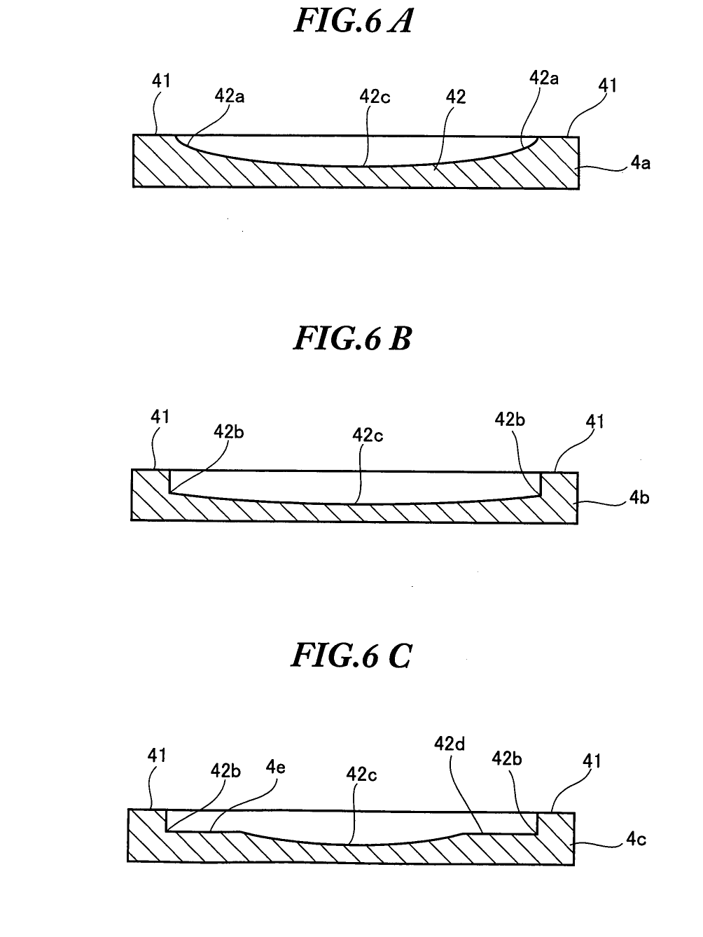

FIGS. 6A to 6C are sectional views showing different types of sealing members for use in self-emission panels according to other embodiments of the present invention. As shown in FIG. 6A, a sealing member 4a is so shaped that the entire inner surface of its concave portion 42 is a curved-surface including an area 42c close to the central portion thereof and areas 42a close to the annular support portion thereof. Further, as shown in FIG. 6B, a sealing member 4b has a concave portion 42 so shaped that it contains corner portions 42b close to the annular support portion thereof. Moreover, as shown in FIG. 6C, a sealing member 4c has a concave portion 42 so shaped that it contains flat portions 42d and corner portions 42b close to the annular support portion thereof. In other words, a sealing member 4 can have any desired shape provided that there would not be any undesired contact among the substrate 2, the self-emission element section 3, the desiccating member 6 disposed on the inner surface of the sealing member 4 or on the inner surface of the concave portion 42 of the sealing member 4.

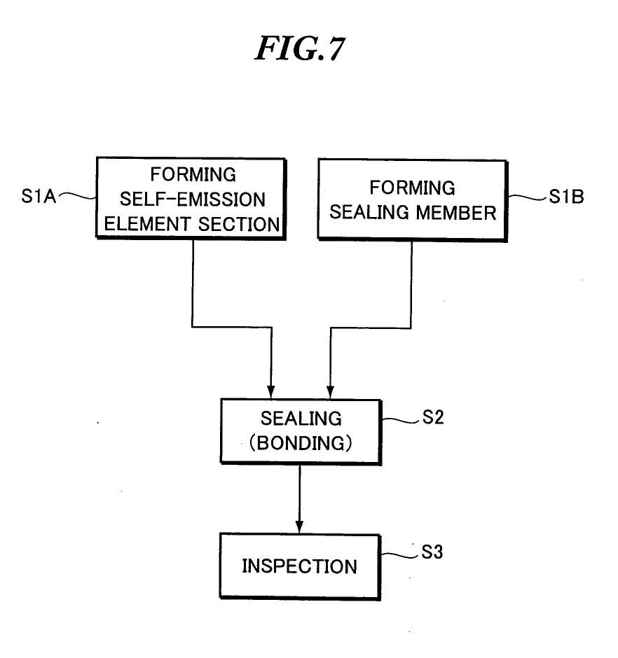

FIG. 7 is a flowchart showing a method of manufacturing a self-emission panel according to one embodiment of the present invention. In fact, FIG. 7 is used to explain a method of manufacturing a self-emission panel according to a fourth embodiment of the present invention. At first, in step S1A for forming a self-emission element section, an organic EL laminated body formed by successively laminating a first electrode, an organic layer, and a second electrode is formed on the substrate 2, thereby forming a self-emission element section 3 formed by interposing at least an organic layer between a pair of electrodes. In practice, what are employed in this method include a well-known film formation process and a well-known patterning process which are usually performed for forming organic EL elements. Further, the self-emission element section 3 can be formed by arranging a plurality of organic EL elements in an array of dot matrix or by arranging one or more organic EL elements in one of any other desired patterns.

On the other hand, in step S1B for forming a sealing member, the above-described sealing member 4 is formed in the above-described manner. At this time, the sealing member 4 is formed in a manner such that it can surround the self-emission element section 3, and such sealing member 4 has an annular support portion 41 to be supported on the substrate 2 and a concave portion 42 formed on one surface of the sealing member 4 facing the self-emission element section 3. Such concave portion 42 has the largest depth in an area 42c close to the center thereof and the smallest depth in areas close to the annular support portion 41. Afterwards, shallow cuts are formed on the inner surface of the concave portion 42 of the sealing member 4, and a sheet-like desiccating member 6 having a desired pattern corresponding to the shallow cuts is disposed on the inner surface of the concave portion 42 of the sealing member 4.

Next, in a sealing step S2, an adhesive agent 5 is applied to the perimeter of the substrate 2 or the bonding surface of the annular support portion 41 of the sealing member 4, followed by bonding the sealing member 4 on to the substrate 2 so as to seal up the self-emission element section 3. In more detail, the substrate 2 and the sealing member 4 formed in the sealing member formation step S1B are bonded together through the annular support portion 41 of the sealing member 4, thereby covering the self-emission element section 3 formed on the substrate 2 and thus completing the sealing process. Subsequently, if necessary, an inspection step S3 is carried out to check the finally formed panel, thereby producing the self-emission panel of the present embodiment.

The sealing member formation step S1B for forming the sealing member 4, as included in the flowchart shown in FIG. 7, employs a process which may be sandblasting, etching, or press molding, so as to form the sealing member into a predetermined desired shape.

Moreover, when a sealing member 4 having a concave portion 42 is formed by a sandblasting process, the opening of a mask can be enlarged gradually while the sealing member is etched by means of an etching process, thereby forming the concave portion 42 and the annular support section 41 in the sealing member 4.

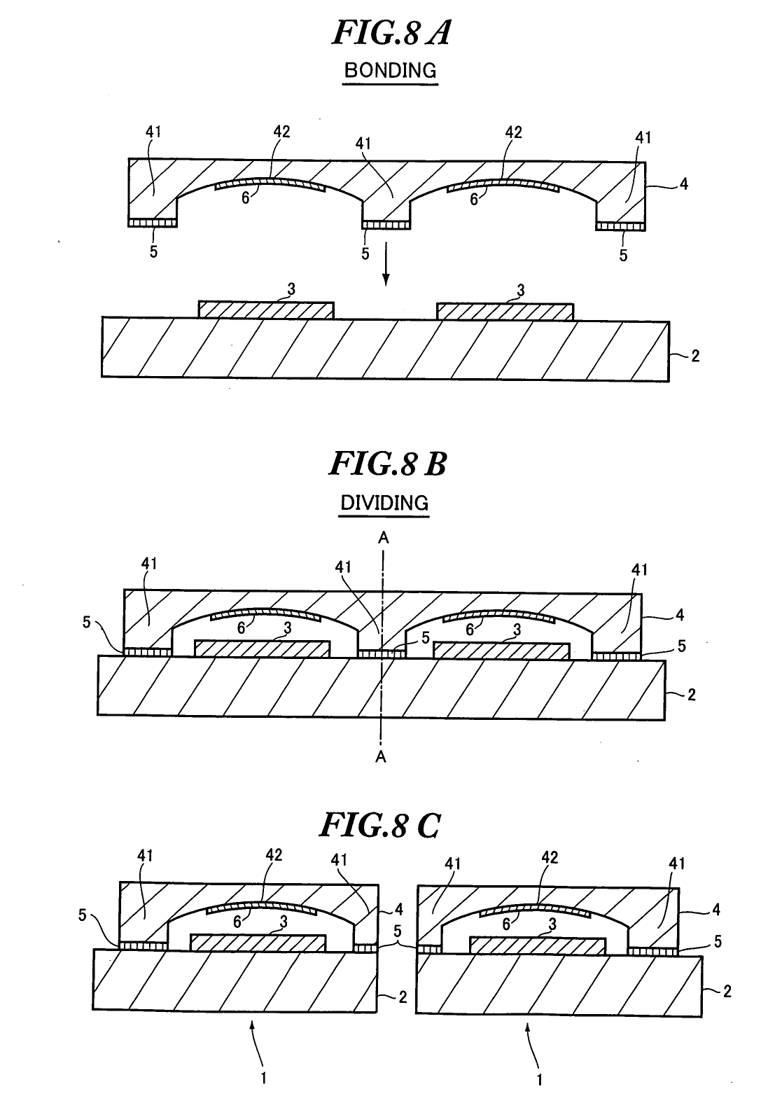

FIGS. 8A to 8C are sectional views showing a method of manufacturing a plurality of self-emission panels according to a further embodiment of the present invention. As shown in FIG. 8A, step S1A for forming self-emission element sections 3 is carried out to form a plurality of self-emission element sections 3 on a substrate 2. Then, step S1B for forming sealing members is carried out to form a plurality of mutually connected sealing members 4 each having a desiccating member 6, followed by applying an adhesive agent 5 to bonding areas of the sealing members 4. In this way, a plurality of self-emission element sections 3 are arranged on the substrate 2 and concave portions 42 are arranged on the sealing members 4 at predetermined intervals. Afterwards, as shown in FIG. 8B, step S2 for performing a sealing process is carried out to bond together the substrate 2 and the sealing members 4 through the adhesive agent 5, followed by cutting along dividing planes (A-A) close to the support portions 41, thereby forming a plurality of self-emission panels.

As described above, according to the manufacturing method of the present embodiment, a plurality of concave portions 42 are formed at a predetermined interval on the sealing members 4, while a plurality of self-emission element sections 3 are formed on the substrate 2 in positions corresponding to the concave portions 42, followed by bonding together the substrate 2 and the sealing members 4 and cutting along dividing planes (A-A) close to the support portions 41, thereby producing a plurality of self-emission panels through the above-described simplified process.

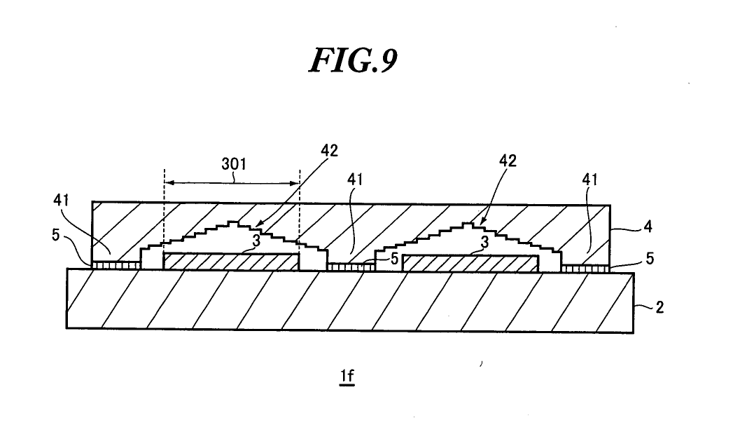

FIG. 9 is a sectional view showing self-emission panels formed according to a further embodiment of the present invention. The embodiment of FIG. 9 is different from the embodiment of FIG. 8 in that the sealing members have stair-like concave portions 42. Similar to the foregoing embodiments, such stair-like concave portions 3 are shaped in a manner such that there would not be an undesired contact between the self-emission element sections 3 formed on the substrate 2 (on one hand) and the inner surfaces of the sealing members 4 or the desiccating members 6 (on the other) As described above, since the sealing members 4 of the present embodiment have stair-like concave portions 42, it is allowed to etch the inner surface of each sealing member at a lower precision than the foregoing concave portion 42 having a curved inner surface, thereby making it possible to shorten an operation time necessary for shaping the inner surface of each sealing member. At this time, it is preferable to have a flat portion of each sealing member 42 to be set at a width which is narrower than the formation area of each self-emission element section 3.

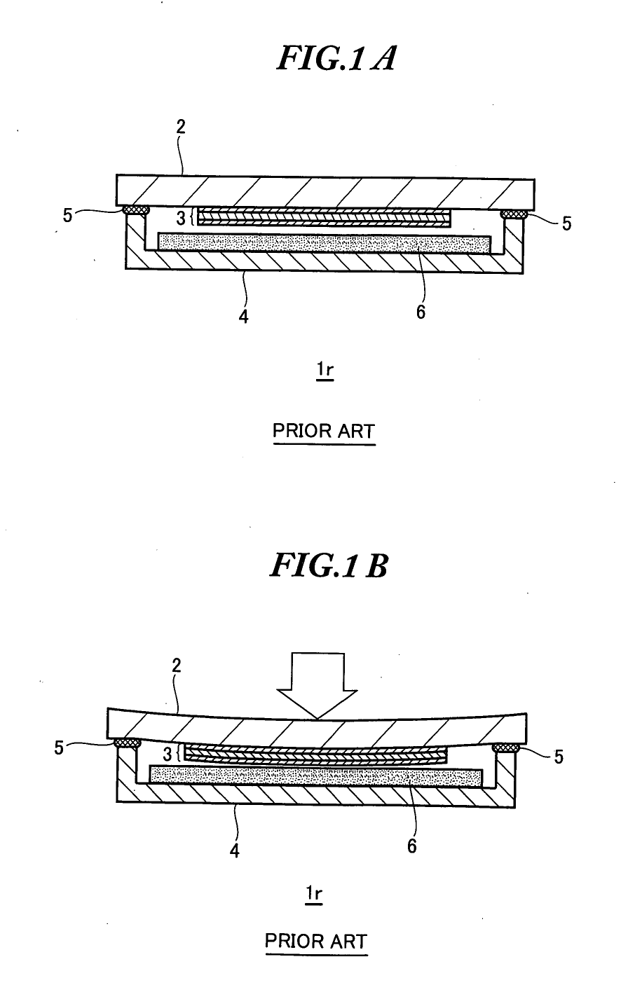

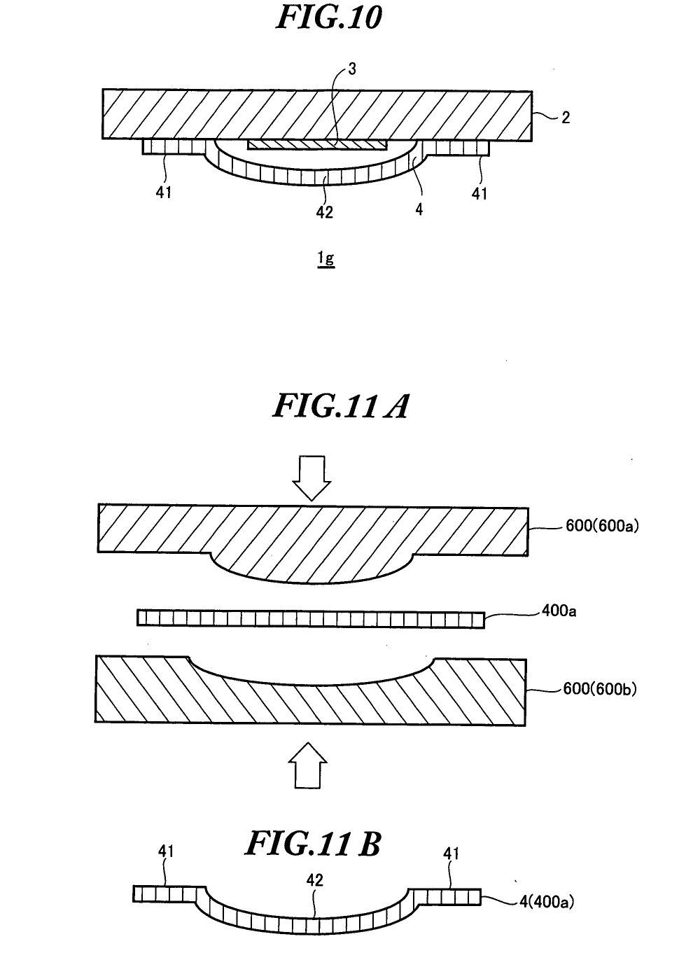

FIG. 10 is a sectional view showing a self-emission panel 1g formed according to a further embodiment of the present invention. As shown in FIG. 10, the self-emission panel of the present embodiment 1g has a sealing member 4 made of a metal material. Such a sealing member 4 can be formed by press molding a metal plate 400a in a metal mould 600 (including a male mould 600a and a female mould 600b), as shown in FIGS. 11A and 1B. Then, the sealing member 4 is bonded on to the substrate 2, thereby producing a self-emission panel.

As described above, the sealing member 4 having the functions of the present invention can be obtained in a shortened time by means of press molding in a simplified process.

Although the above description has been given to explain several embodiments, these embodiments should not form any limitation to the present invention.

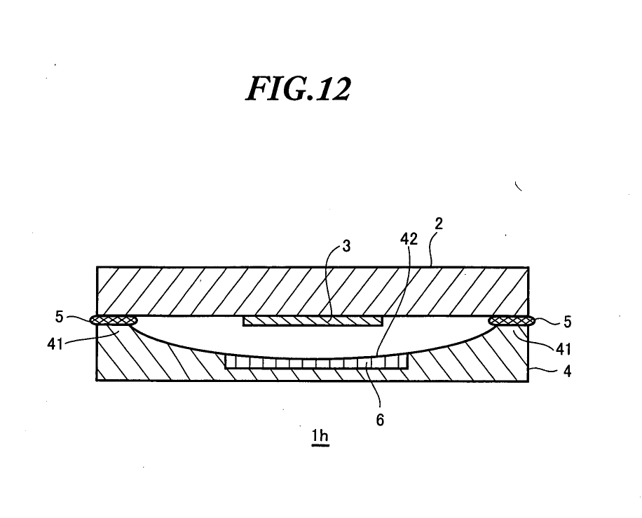

For example, as shown in FIG. 12, the concave portion 42 of the sealing member 4 can be formed with the desiccating member 6 buried therein, which is the deepest near the center 41c and the shallowest near the annular support portion 41. In this way, it is possible for the sealing member 4 to be formed at a small thickness, thereby ensuring a small thickness for an entire self-emission panel.

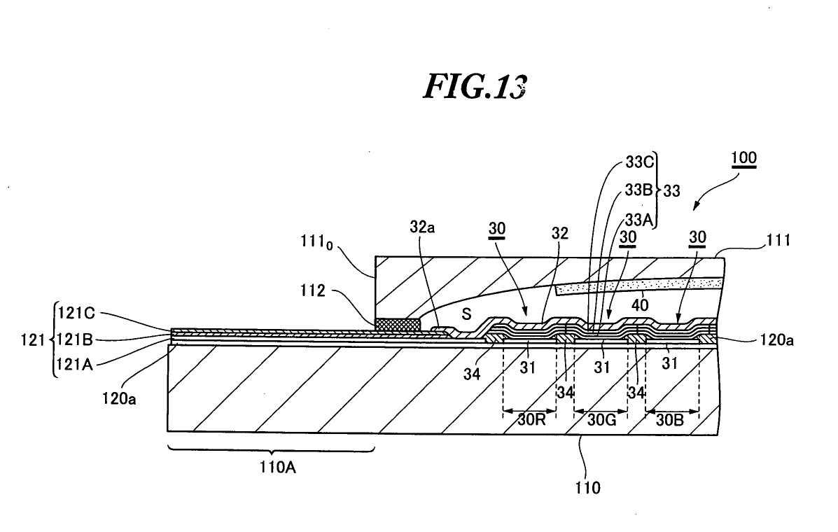

In the following, with reference to FIG. 13, description will be given to explain an organic EL panel serving as an example of the foregoing self-emission electro-optical panel.

As shown, an organic EL panel 100 is formed by interposing an organic layer 33 containing an organic luminescent layer between first electrodes (lower electrodes) 31 on one hand and second electrodes (upper electrodes) 32 on the other, thereby forming a plurality of organic EL elements 30 on the support substrate 110. In an example shown in FIG. 13, a silicon coating layer 120a is formed on the support substrate 110, and a plurality of first electrodes 31 consisting of transparent electrode material such as ITO and serving as anodes are formed on the silicon coating layer 120a. Further, second electrodes 32 consisting of a metal such as Al and serving as cathodes are formed over the first electrodes 31, thereby forming a bottom emission type panel capable of emitting light from the support substrate 110 side. Moreover, the panel also contains an organic layer 33 including a positive hole transporting layer 33A, a luminescent layer 33B, and an electron transporting layer 33C. Then, the support substrate 110 and a sealing member 111 are bonded together through an adhesive layer 112, thereby forming a sealing area S, thus forming a display section consisting of organic EL elements 30 within the sealing area S.

A display section consisting of organic EL elements 30, as shown in an example of FIG. 13, is so formed that its first electrodes 31 are divided by insulating strips 34, thereby forming a plurality of unit display areas (30R, 30G, 30B) by virtue of the respective organic EL elements 30 located under the divided first electrodes 31. Further, desiccating means 40 is attached to the inner surface of the sealing member 111 forming the sealing area S, thereby preventing a deterioration of the organic EL elements which is possibly caused due to moisture.

Moreover, on the lead-out area 110A formed along the edge of the support substrate 110 there is formed a first electrode layer 121A using the same material and the same step as forming the first electrodes 31, which is separated from the first electrodes 31 by the insulating strips 34. Further, on the lead-out portion of the first electrode layer 121A there is formed a second electrode layer 121B forming a low-resistant wiring portion containing a silver alloy or the like. In addition, if necessary, a protection coating layer 121C consisting of IZO or the like is formed on the second electrode layer 121B. In this way, a lead-out wiring portion 121 can be formed which consists of the first electrode layer 121A, the second electrode layer 121B, and the protection coating 121C. Then, an edge portion 32a of each second electrode 32 is connected to the lead-out wiring portion 121 at edge portion of the sealing area S.

Here, although the lead-out wiring portion of each first electrode 31 is not shown in the drawing, such lead-out wiring portion can be formed by extending each first electrode 31 and leading the same out of the sealing area S. Actually, such lead-out wiring portion can also be formed into an electrode layer forming a low resistant wiring portion containing a silver alloy or the like in a manner similar to an example associated with the above-described second electrode 32.

Then, an edge 111EO facing the lead-out wiring portion 121 of the sealing member 111 is formed by a hole processing edge formed before bonding together the support substrate 110 and the sealing member 111.

Next, description will be given in more detail to explain the details of the aforementioned organic EL panel 100.

a. Electrodes

Either the first electrodes 31 or the second electrodes 32 are set as cathode side, while the opposite side is set as anode side. The anode side is formed by a material having a higher work function than the cathode side, using a transparent conductive film which may be a metal film such as chromium (Cr), molybdenum (Mo), nickel (Ni), and platinum (Pt), or a metal oxide film such as ITO and IZO. In contrast, the cathode side is formed by a material having a lower work function than the anode side, using a metal having a low work function, which may be an alkali metal (such as Li, Na, K, Rb, and Cs), an alkaline earth metal (such as Be, Mg, Ca, Sr, and Ba), a rare earth metal, a compound or an alloy containing two or more of the above elements, or an amorphous semiconductor such as a doped polyaniline and a doped polyphenylene vinylene, or an oxide such as Cr₂O₃, NiO, and Mn₂O₅. Moreover, when the first electrodes 31 and the second electrodes 32 are all formed by transparent materials, it is allowed to provide a reflection film on one electrode side opposite to the light emission side.

The lead-out wiring portion (the lead-out wiring portion 121 and the lead-out wiring portion of the first electrodes 31, as shown in the figure) are connected with drive circuit parts driving the organic EL panel 100 or connected with a flexible wiring board. However, it is preferable for these lead-out wiring portions to be formed as having a low resistance as possible. Namely, the lead-out wiring portions can be formed by laminating low resistant metal electrode layers which may be Ag-alloy, Cr, Al, or the like. Alternatively, they may be formed by single one electrode of low resistant metal.

b. Organic layer

Although the organic layer 33 comprises one or more layers of organic compound materials including at least one organic luminescent layer, its laminated structure can be in any desired arrangement. Usually, in the case of a low molecule organic EL material, as shown in FIG. 13, there is a laminated structure including, from the anode side towards the cathode side, a hole transporting layer 33A, a luminescent layer 33B, and an electron transporting layer 33C. Each of the hole transporting layer 33A, the luminescent layer 33B, and the electron transporting layer 33C can be in a single-layer or a multi-layered structure. Moreover, it is also possible to dispense with the hole transporting layer 33A and/or the electron transporting layer 33C. On the other hand, if necessary, it is allowed to insert other organic layers including a hole injection layer, and an electron injection layer. Here, the hole transporting layer 33A, the luminescent layer 33B, and the electron transporting layer 33C can be formed by any conventional materials (it is allowed to use either a high molecular material or a low molecular material).

Regarding to a luminescent material for forming the luminescent layer 33B, it is allowed to make use of a luminescence (fluorescence) obtained when the material returns from a singlet excited state to a base state or a luminescence (phosphorescence) obtained when it returns from a triplet excited state to a base state.

c. Sealing Member

In the organic EL panel 100, the covering member for tightly covering organic EL elements 30 may be a plate-like member or container-like member made of metal, glass, or plastic. Here, the sealing member may be a piece of material having a recess portion (a one-step recess or a two-step recess) formed by pressing, etching, or blasting. Alternatively, the sealing member may be formed by using a flat glass plate capable of forming a sealing area S between the flat glass plate and the support substrate 110 by virtue of a spacer made of glass (or plastic).

d. Adhesive Agent

An adhesive agent forming the adhesive layer 112 may be a thermal-setting type, a chemical-setting type (two-liquid mixture), or a light (ultraviolet) setting type, which can be formed by an acryl resin, an epoxy resin, a polyester, a polyolefin. Particularly, it is preferable to use an ultraviolet-setting epoxy resin adhesive agent which is quick to solidify without a heating treatment.

e. Desiccating Means

Desiccating means 40 may be a physical desiccating agent such as zeolite, silica gel, carbon, and carbon nanotube; a chemical desiccating agent such as alkali metal oxide, metal halide, chlorine dioxide; a desiccating-agent formed by dissolving an organometal complex in a petroleum system solvent such as toluene, xylene, an aliphatic organic solvent and the like; and a desiccating agent formed by dispersing desiccating particles in a transparent binder such as polyethylene, polyisoprene, polyvinyl thinnate.

f. Various Types of Organic EL Panels

The organic EL panel 100 of the present invention can have various types without departing from the scope of the invention. For example, the light emission type of organic EL elements 30 can be bottom emission type which emit light from the substrate 110 side, or top emission type which emit light from the sealing member 111 side (at this time, it is necessary for the sealing member 111 to be made of a transparent material and to dispose the desiccating means 40) . Moreover, an organic EL display panel 100 may be a single color display or a multi-color display. In order to form a multi-color display, it is possible to adopt a discriminated painting method or a method in which a single color (white or blue) luminescent layer is combined with a color conversion layer formed by a color filter or a fluorescent material (CF manner, CCM manner), a photo bleaching method which realizes a multiple light emission by emitting an electromagnetic wave or the like to the light emission area of a single color luminescent layer, a SOLED (transparent Stacked OLED) method in which two or more colors of unit display areas are laminated to form one unit display area, or a laser transfer method in which low molecular organic materials having different luminescent colors are deposited in advance on to different films and then transferred to one substrate by virtue of thermal transfer using a laser. Besides, although the accompanying drawings show only a passive driving manner, it is also possible to adopt an active driving manner by adopting TFT substrate serving as support substrate 110, forming thereon a flattening layer, and further forming the first electrodes 31 on the flattening layer.

As described above, using the self-emission panel and the method of manufacturing the same or using the sealing member of the self-emission panel, it is possible to obtain the following advantages. Namely, even if the panel substrate is bent, it is possible to avoid an undesired contact between the self-emission element section formed on the substrate (on one hand) and the sealing member or a desiccating member disposed with a sealing space (on the other). Further, it is possible not only to avoid the aforementioned undesired contact, but also to ensure an adequate strength for the sealing member. Therefore, it becomes possible to provide an improved display panel which is large in size and small in thickness without incurring any trouble.

While there has been described what are at present considered to be preferred embodiments of the present invention, it will be understood that various modifications may be made thereto, and it is intended that the appended claims cover all such modifications as fall within the true spirit and scope of the invention.

What is claimed is:

1. A self-emission panel fabricated by forming a self-emission element section on a substrate, followed by bonding together the substrate and a sealing member so as to form a sealing space to dispose the self-emission element section within the sealing space,
wherein the sealing member is adhesively supported on the substrate through a support portion disposed around the self-emission element section; and
wherein the sealing member has a concave portion formed on one surface thereof facing the self-emission element section, the concave portion's central area surrounded by the support portion being the deepest and the concave portion's other areas becoming shallow towards the support portion.

2. The self-emission panel according to claim 1, wherein a maximum depth of said concave portion is set in response to a maximum bending amount of said substrate being bent into said sealing space.

3. A sealing member for use in a self-emission panel, wherein a substrate having formed thereon a self-emission element section and a sealing member are bonded together to form a sealing space, thereby allowing the self-emission element section to be disposed within the sealing space,
said sealing member comprising:
a support portion formed to surround the self-emission element section and to be adhesively supported on the substrate; and
a concave portion formed on one surface of the sealing member facing the self-emission element section, the concave portion's central area surrounded by the support portion being the deepest and the concave portion's other areas becoming shallow towards the support portion.

4. The sealing member according to claim 3, wherein a maximum depth of said concave portion is set in response to a maximum bending amount of said substrate being bent into said sealing space.

5. A method of manufacturing a self-emission panel formed by bonding together i) a substrate having formed thereon a self-emission element section and ii) a sealing member so as to form a sealing space, thereby allowing the self-emission element section to be disposed within the sealing space, said method comprising:
a first step for forming the sealing member having a support portion to surround the self-emission element section and to be adhesively supported on the substrate, also having a concave portion formed on one surface of the sealing member facing the self-emission element section, the concave portion's central area surrounded by the support portion being the deepest and the concave portion's other areas becoming shallow towards the support portion; and
a second step for bonding together the substrate and the sealing member formed in the first step through the support portion, in a manner such that the self-emission element section formed on the substrate is surrounded and covered by the sealing member.

6. The method according to claim 5, wherein the first step is carried out to gradually enlarge the opening of a mask placed on the sealing member, and at the same time to dig into the sealing member through the opening of the mask, thereby forming said concave portion in the sealing member.
